(19) United States
(12) Patent Application Publication
(10) Pub. No.: US 2025/0232092 A1
(43) Pub. Date: Jul. 17, 2025

(54) Model Emulation

(71) Applicant: The Boeing Company, Arlington, VA (US)

(72) Inventors: Deepak Khosla, Arlington, VA (US); Joshua G. Fadaie, Calabasas, CA (US); Charles Tullock, St. Peters, MO (US); Nathan Hemming, Grand Forks, ND (US); Arya Ketabchi Haghighat, Woodland Hills, CA (US)

(21) Appl. No.: 18/414,387

(22) Filed: Jan. 16, 2024

(51) Int. Cl. G06F 30/27; G06F 30/15

(52) U.S. Cl. CPC G06F 30/27; G06F 30/15

(57) ABSTRACT

An example includes a method of training a first computational model to emulate a second computational model. The method includes using the first computational model to generate a first output in response to receiving an input and selecting a reward based on whether a difference between the first output and a second output is less than a threshold. The second output is generated by the second computational model in response to receiving the input. The method further includes updating the first computational model using the reward.

### FIELD

The present disclosure relates generally to training a computational model, and more specifically to training a first computational model to emulate a second computational model.

### BACKGROUND

Conventional software models can accurately predict outcomes of air-to-air combat scenarios, but can require large amounts of digital memory for implementation. Additionally, such models often have low throughput when implemented on the hardware systems that are typically available on aircraft. As such, a need exists for a model that can accurately predict outcomes of air-to-air combat scenarios using less memory and computing resources.

### SUMMARY

One aspect of the disclosure is a method of training a first computational model to emulate a second computational model, the method comprising: (a) using the first computational model to generate a first output in response to receiving an input; (b) selecting a reward based on whether a difference between the first output and a second output is less than a threshold, wherein the second output is generated by the second computational model in response to receiving the input; and (c) updating the first computational model using the reward.

Another aspect of the disclosure is a non-transitory computer readable medium storing instructions that, when executed by one or more processors of a computing device, cause the computing device to perform functions for training a first computational model to emulate a second computational model, the functions comprising: (a) using the first computational model to generate a first output in response to receiving an input; (b) selecting a reward based on whether a difference between the first output and a second output is less than a threshold, wherein the second output is generated by the second computational model in response to receiving the input; and (c) updating the first computational model using the reward.

Another aspect of the disclosure is a computing device comprising: one or more processors; and a computer readable medium storing instructions that, when executed by the one or more processors, cause the computing device to perform functions for training a first computational model to emulate a second computational model, the functions comprising: (a) using the first computational model to generate a first output in response to receiving an input; (b) selecting a reward based on whether a difference between the first output and a second output is less than a threshold, wherein the second output is generated by the second computational model in response to receiving the input; and (c) updating the first computational model using the reward.

By the term “about” or “substantially” with reference to amounts or measurement values described herein, it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

The features, functions, and advantages that have been discussed can be achieved independently in various examples or may be combined in yet other examples further details of which can be seen with reference to the following description and drawings.

### BRIEF DESCRIPTION OF THE DRAWINGS

The novel features believed characteristic of the illustrative examples are set forth in the appended claims. The illustrative examples, however, as well as a preferred mode of use, further objectives and descriptions thereof, will best be understood by reference to the following detailed description of an illustrative example of the present disclosure when read in conjunction with the accompanying Figures.

FIG. 1 is a block diagram of a computing device, according to an example.

FIG. 2 is a schematic diagram of operations of a computing device, according to an example.

FIG. 3 is a schematic diagram of operations of a computing device, according to an example.

FIG. 4 a schematic diagram of operations of a computing device, according to an example.

FIG. 5 is a block diagram of a method, according to an example.

FIG. 6 is a block diagram of a method, according to an example.

FIG. 7 is a block diagram of a method, according to an example.

FIG. 8 is a block diagram of a method, according to an example.

### DETAILED DESCRIPTION

As noted above, a need exists for a model that can accurately predict outcomes of air-to-air combat scenarios using less memory and less computing resources. Accordingly, this disclosure includes methods and systems for building and training such a model.

The disclosure includes a method of training a first computational model (e.g., a machine learning model) to emulate a second computational model (e.g., a theoretical model, a simulated model, and/or a mathematical model). For example, the first computational model is trained to recognize patterns that relate inputs and outputs whereas the second computational model might generate outputs by processing inputs using many equations and/or rules.

The method includes using the first computational model to generate a first output in response to receiving an input. In various examples, the input could include altitudes and/or velocities of two aircraft engaged in air-to-air combat, an aspect angle and/or a lead angle between the two aircraft, a maximum acceleration capability of the two aircraft, and/or a type of missile carried by one of the aircraft. Generally, the input defines an initial condition of the air-to-air combat scenario that involves the first aircraft and the second aircraft. The first output can include a distance over which a missile deployed by the first aircraft travels to reach the second aircraft and/or a time of flight for the missile deployed by the first aircraft to reach the second aircraft.

The method also includes selecting a reward based on whether a difference between the first output and a second output is less than a threshold. The second output is generated by the second computational model in response to receiving the same input provided to the first computational model. The first computational model should generally emulate the second computational model very accurately and precisely because human pilots may rely on the predictions of the first computational model in dangerous combat situations. Thus, the threshold (e.g., error tolerance) is typically selected to be small. In some examples, if the difference between the first output and the second output is less than the threshold, a positive reinforcement reward is selected. However, if the difference between the first output and the second output is greater than the threshold, a negative reinforcement reward is selected. The magnitude of the negative reinforcement reward can be selected in proportion to the degree to which the difference between the first output and the second output exceeds the threshold. Lastly, the method includes updating the first computational model using the reward.

The first computational model can be iteratively trained in this way using different combinations of inputs, comparing the resultant output generated by the first computational model and the second computational model, and rewarding the first computational model positively or negatively depending on how closely the output of the first computational model matches the output of the second computational model.

Disclosed examples will now be described more fully hereinafter with reference to the accompanying Drawings, in which some, but not all of the disclosed examples are shown. Indeed, several different examples may be described and should not be construed as limited to the examples set forth herein. Rather, these examples are described so that this disclosure will be thorough and complete and will fully convey the scope of the disclosure to those skilled in the art.

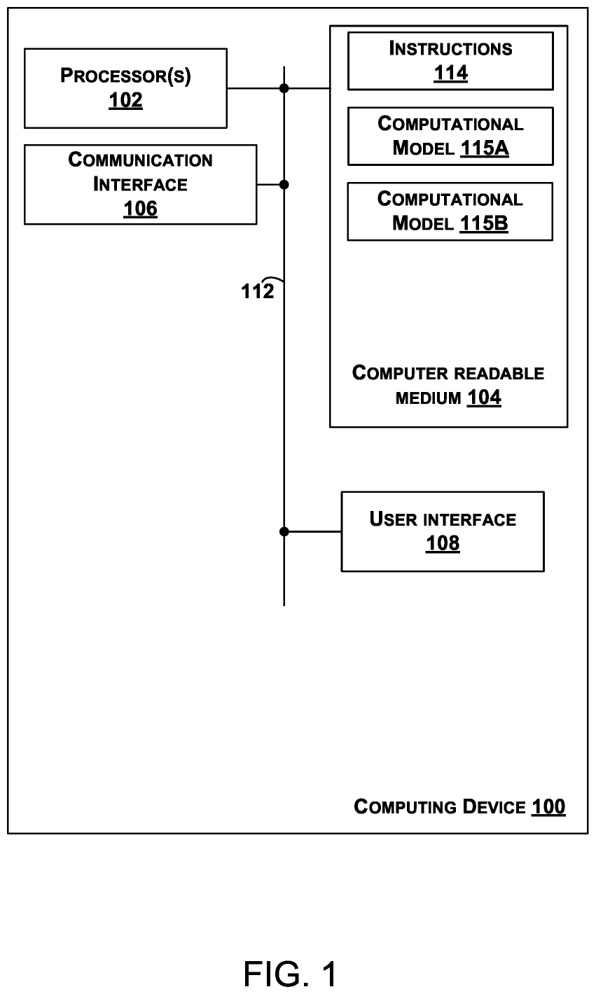

FIG. 1 is a block diagram of a computing device 100. The computing device 100 includes one or more processors 102, a non-transitory computer readable medium 104, a communication interface 106, and a user interface 108. Components of the computing device 100 are linked together by a system bus, network, or other connection mechanism 112.

The one or more processors 102 can be any type of processor(s), such as a microprocessor, a field programmable gate array, a digital signal processor, a multicore processor, etc., coupled to the non-transitory computer readable medium 104.

The non-transitory computer readable medium 104 can be any type of memory, such as volatile memory like random access memory (RAM), dynamic random access memory (DRAM), static random access memory (SRAM), or non-volatile memory like read-only memory (ROM), flash memory, magnetic or optical disks, or compact-disc read-only memory (CD-ROM), among other devices used to store data or programs on a temporary or permanent basis.

Additionally, the non-transitory computer readable medium 104 can store instructions 114. The instructions 114 are executable by the one or more processors 102 to cause the computing device 100 to perform any of the functions or methods described herein. The non-transitory computer readable medium 104 can additionally store the computational model 115A and the computational model 115B. Thus, the one or more processors 102 can execute the instructions 114 to train the computational model 115A.

The communication interface 106 can include hardware to enable communication within the computing device 100 and/or between the computing device 100 and one or more other devices. The hardware can include any type of input and/or output interfaces, a universal serial bus (USB), PCI Express, transmitters, receivers, and antennas, for example. The communication interface 106 can be configured to facilitate communication with one or more other devices, in accordance with one or more wired or wireless communication protocols. For example, the communication interface 106 can be configured to facilitate wireless data communication for the computing device 100 according to one or more wireless communication standards, such as one or more Institute of Electrical and Electronics Engineers (IEEE) 801.11 standards, ZigBee standards, Bluetooth standards, etc. As another example, the communication interface 106 can be configured to facilitate wired data communication with one or more other devices. The communication interface 106 can also include analog-to-digital converters (ADCs) or digital-to-analog converters (DACs) that the computing device 100 can use to control various components of the computing device 100 or external devices.

The user interface 108 can include any type of display component configured to display data. As one example, the user interface 108 can include a touchscreen display. As another example, the user interface 108 can include a flat-panel display, such as a liquid-crystal display (LCD) or a light-emitting diode (LED) display. The user interface 108 can include one or more pieces of hardware used to provide data and control signals to the computing device 100. For instance, the user interface 108 can include a mouse or a pointing device, a keyboard or a keypad, a microphone, a touchpad, or a touchscreen, among other possible types of user input devices. Generally, the user interface 108 can enable an operator to interact with a graphical user interface (GUI) provided by the computing device 100 (e.g., displayed by the user interface 108).

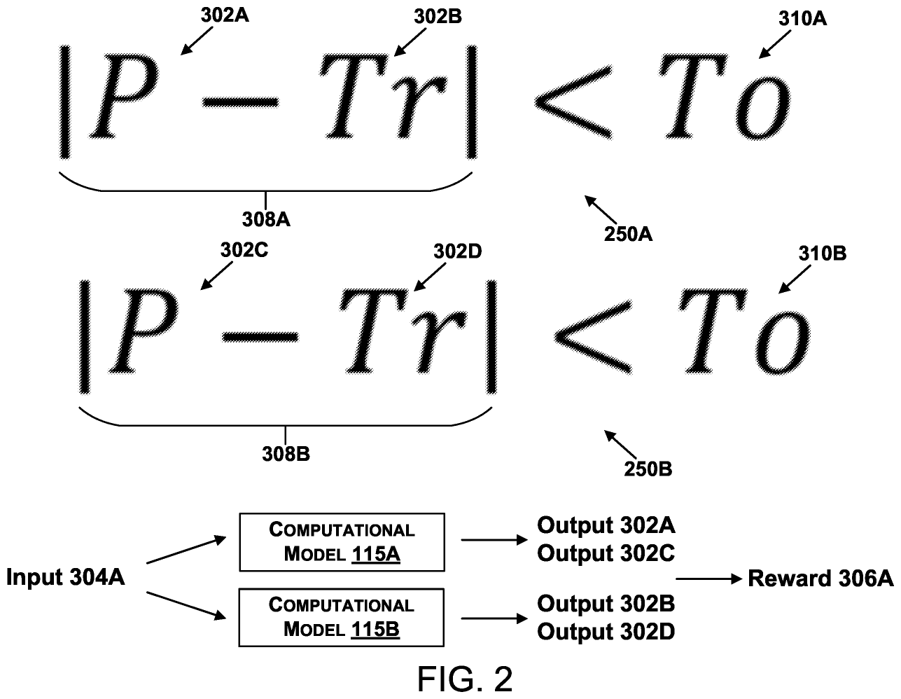

FIG. 2 shows a condition 250A related to the computational model 115A (e.g., a machine learning model) and the computational model 115B (e.g., a theoretical model, a simulated model, and/or a mathematical model). The computational model 115A could take the form of an artificial neural network, a convolutional neural network, a decision tree, a reinforcement learning model, a supervised learning model, or the like. More particularly, the condition 250A is used to compare respective outputs generated by the computational model 115A and the computational model 115B when given a common input, and to train the computational model 115A to better emulate the computational model 115B.

For example, the computing device 100 uses the computational model 115A to generate an output 302A in response to receiving an input 304A. In various examples, the input 304A could include altitudes and/or velocities of two aircraft engaged in air-to-air combat, an aspect angle and/or a lead angle between the two aircraft, a maximum acceleration capability of one or more of the two aircraft, and/or a type of missile carried by the first aircraft and/or the range of the missile. Generally, any inputs 304 and/or outputs 302 can take the form of a matrix in some examples.

The altitudes of the aircraft are generally expressed with reference to sea level, but other examples are possible. The velocities of the aircraft are generally expressed with an absolute speed and a three-dimensional direction or vector of movement. The aspect angle is generally the angle between two vectors originating from the second aircraft's nose. A first vector points to the second aircraft's tail and the other points to the first aircraft's nose. The lead angle is generally the angle between the velocity vector of the first aircraft and the line-of-sight of the second aircraft or the direction that the nose of the second aircraft is pointing.

The output 302A can include a distance (e.g., expressed in meters or kilometers) over which a missile deployed by the first aircraft travels to reach the second aircraft or a time of flight (e.g., expressed in seconds) for the missile deployed by the first aircraft to reach the second aircraft.

Each distance (e.g., missile range) prediction included in the output 302A could have a minimum range, a no-escape range, and a maximum range. The minimum range is the minimum distance the missile could travel given the current state of the aircrafts and still hit the second aircraft. The maximum range is the maximum distance the missile could travel given the current state of the aircrafts and still hit the second aircraft. The no-escape distance is the distance between the first aircraft and the second aircraft, given the current state of the aircrafts, that lead to the missile hitting the second aircraft, if the second aircraft uses maximum acceleration to turn away and evade the missile.

The missile time of flight prediction also has a minimum, maximum, and no-escape value. The minimum time is the least amount of time the missile could travel given the current state of the aircrafts and still hit the second aircraft. The maximum time is the greatest amount of time the missile could travel given the current state of the aircrafts and still hit the second aircraft. The no-escape time is the missile travel time, given the current state of the aircrafts, that lead to the missile hitting the second aircraft, if the second aircraft uses maximum acceleration to turn away and evade the missile.

In this way, the machine learning model learns to predict the weapons envelope (e.g. the regions in which a missile hit can occur). If the model predicts a non-zero time of flight and range, and the distance between the target and shooter aircraft are within the ranges predicted by the model, then a hit can likely occur.

Next, the computing device 100 selects a reward 306A based on whether a difference 308A (e.g., an absolute difference) between the output 302A and an output 302B is less than a threshold 310A (e.g., 40 meters or 300 milliseconds). The output 302B is generated by the computational model 115B in response to receiving the input 304A. Similar to the output 302A, the output 302B generally includes a distance (e.g., expressed in meters or kilometers) over which the missile deployed by the first aircraft travels to reach the second aircraft or a time of flight (e.g., expressed in seconds) for the missile deployed by the first aircraft to reach the second aircraft.

The computing device 100 updates the computational model 115A using the reward 306A. For example, the computing device 100 can alter edges or nodes of the computational model 115A using the reward 306A. Given a positive reward 306A, the computing device 100 could alter the computational model 115A such that the computational model 115A is more likely to generate an output equal to the output 302A when given the input 304A. Given a negative reward 306A, the computing device 100 could alter the computational model 115A such that the computational model 115A is less likely to generate an output equal to the output 302A when given the input 304A.

In some examples, the computing device 100 provides the computational model 115A and the computational model 115B a first common input during a first iteration, a second common input during a second iteration, a third common input during a third iteration, and so on. For each training iteration, the computing device 100 selects a reward based on whether the difference between the output of the computational model 115A and the output of the computational model 115B satisfies a threshold. For each iteration, the computational model 115A is provided the reward (e.g. or penalty) corresponding to whether the difference between the output of the computational model 115A and the output of the computational model 115B, when provided a particular common input, satisfies the threshold. Generally, the computing device 100 updates the computational model 115A with a positive reward if the difference is less than the threshold and updates the computational model 115A with a negative reward if the difference is greater than the threshold.

In some examples, the computing device 100 selects the reward 306A based on comparisons of two pairs of outputs, that is, based on the condition 250B in addition to the condition 250A. For instance, the output 302A and the output 302B could be distances over which the missile deployed by the first aircraft travels to reach the second aircraft and the output 302C and the output 302D could be a time of flight for the missile deployed by the first aircraft to reach the second aircraft. As such, the computing device 100 selects the reward 306A based on how accurately the computational model 115A predicts the missile travel distance and time.

For example, the computing device 100 uses the computational model 115A to generate the output 302C in response to receiving the input 304A. Thus, the computing device 100 selects the reward 306A additionally based on whether a difference 308B between the output 302C and the output 302D is less than a threshold 310B. The output 302D is generated by the computational model 115B in response to receiving the input 304A.

In some examples, the computing device 100 selects the reward 306A to be a positive reinforcement reward based on (a) the difference 308A being less than the threshold 310A and (b) the difference 308B being less than the threshold 310B.

In some examples, the computing device 100 selects the reward 306A to be a negative reinforcement reward based on (a) the difference 308A being greater than the threshold 310A or (b) the difference 308B being greater than the threshold 310B.

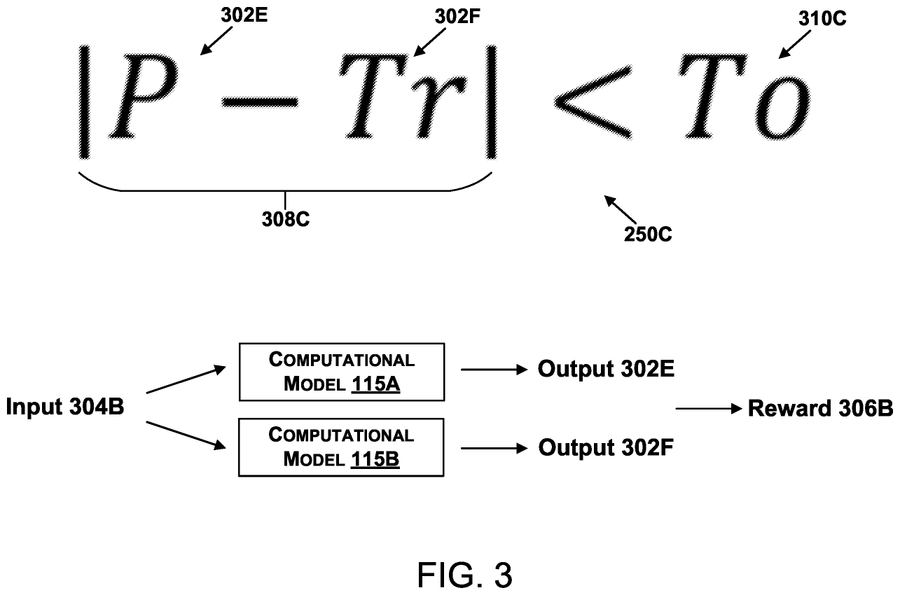

Referring to FIG. 3, in some examples the computing device 100 provides a more pronounced negative reward to the computational model 115A if the difference between outputs of the computational model 115A and the computational model 115B exceeds a larger threshold, using the condition 250C. For example, the computing device 100 uses the computational model 115A to generate an output 302E in response to receiving an input 304B. The computing device 100 selects a reward 306B in the form of a negative reinforcement reward based on a difference 308C between the output 302E and an output 302F being greater than a threshold 310C. The output 302F is generated by the computational model 115B in response to receiving the input 304B. The threshold 310C is greater than the threshold 310A. The reward 306B has a greater magnitude than the reward 306A. In this example, the reward 306A and the reward 306B are both negative reinforcement rewards. The computing device 100 updates the computational model 115A using the reward 306B.

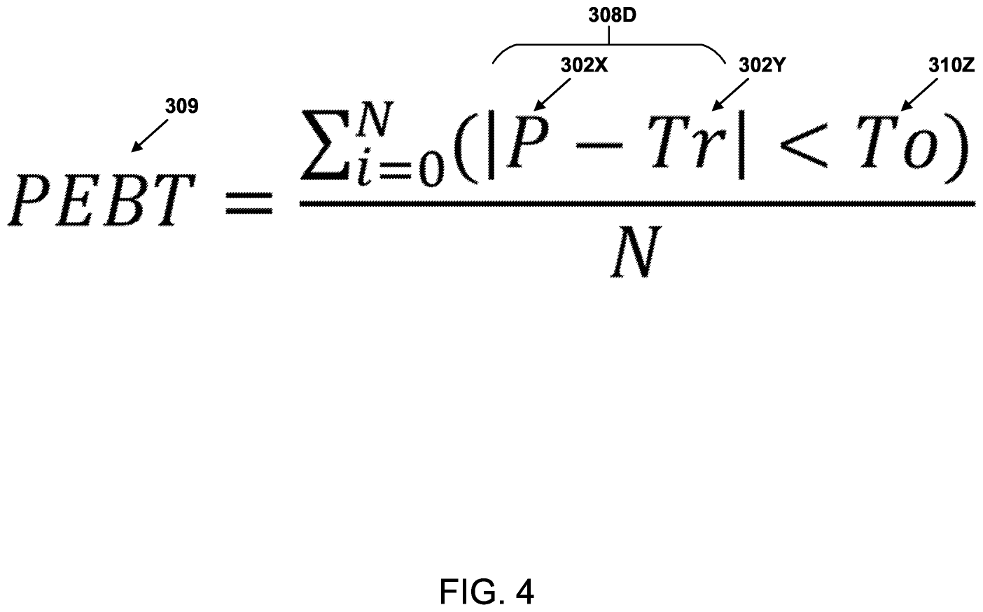

Referring to FIG. 4, the computing device 100 can be used to evaluate how well the computational model 115A emulates the computational model 115B. For example, the computing device 100 uses the computational model 115A to generate multiple outputs 302X in response to receiving respective inputs 304. The computing device 100 then determines a proportion 309 of differences 308 between the ‘N’ outputs 302X and the ‘N’ outputs 302Y that are less than a threshold 310Z. The outputs 302Y are generated by the computational model 115B in response to receiving the inputs 304. Thus, the proportion 309 can range from 0 to 1 and is a metric for how well the computational model 115A produces output that matches output of the computational model 115B within a defined threshold.

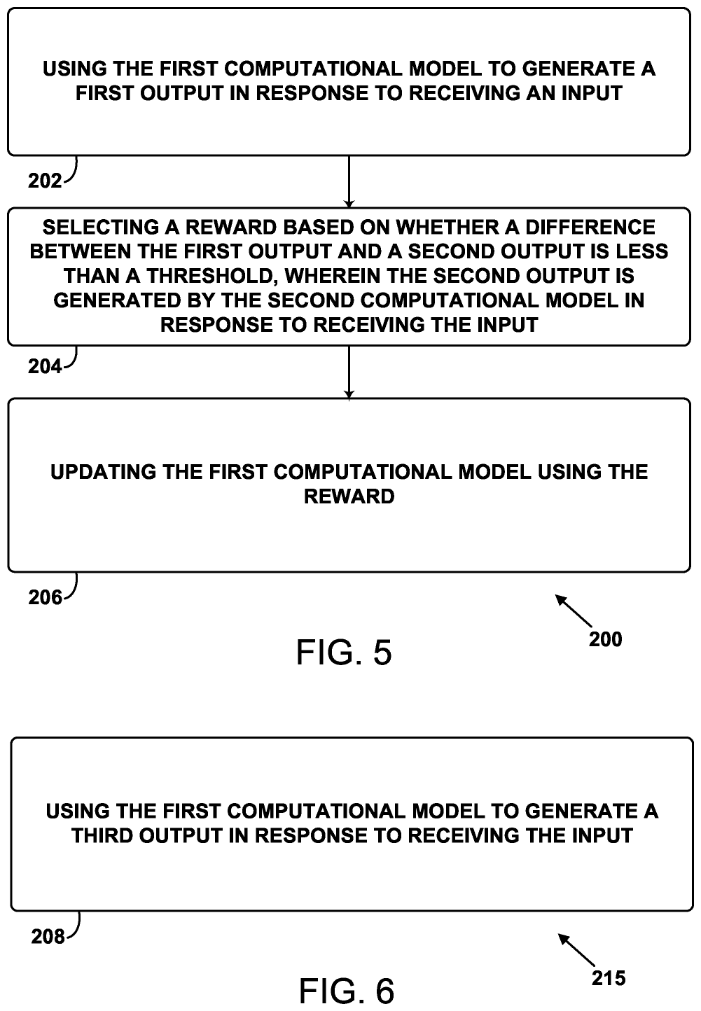

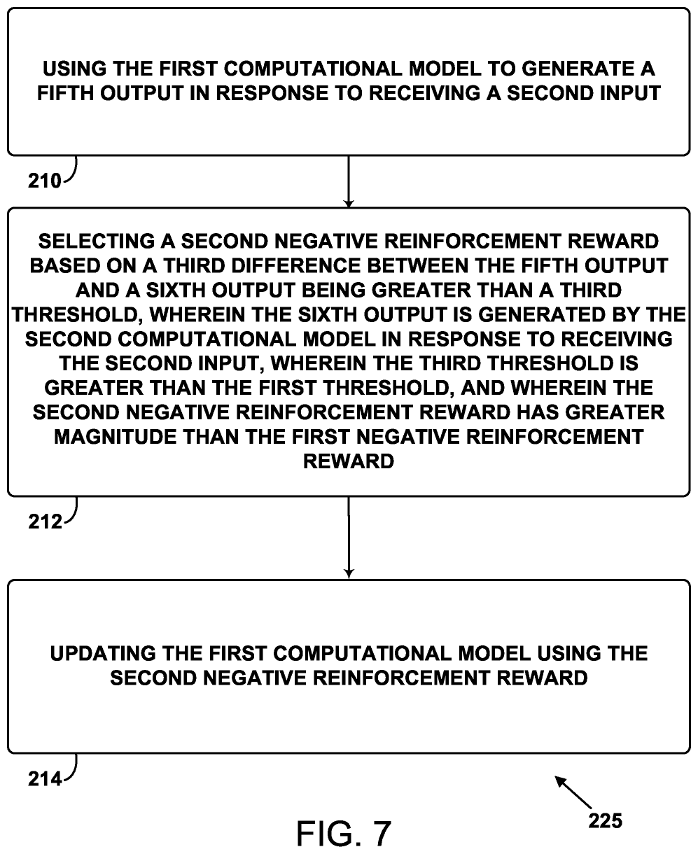

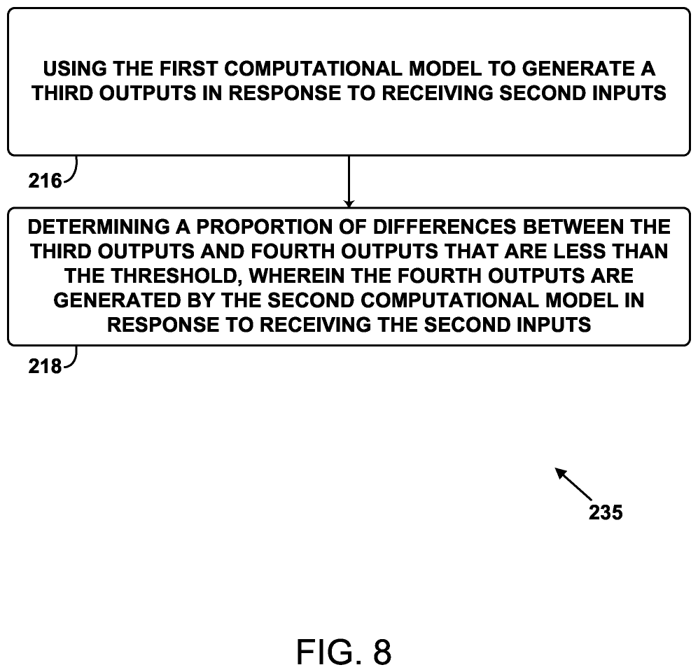

FIGS. 5-8 are block diagrams of a method 200, a method 215, a method 225, and a method 235, which in some examples are performed by the computing device 100. As shown in FIGS. 5-8, the method 200, the method 215, the method 225, and the method 235 include one or more operations, functions, or actions as illustrated by blocks 202, 204, 206, 208, 210, 212, 214, 216, and 218. Although the blocks are illustrated in a sequential order, these blocks may also be performed in parallel, and/or in a different order than those described herein. Also, the various blocks may be combined into fewer blocks, divided into additional blocks, and/or removed based upon the desired implementation.

At block 202, the method 200 includes using the computational model 115A to generate the output 302A in response to receiving the input 304A. Functionality related to block 202 is described above with reference to FIG. 2.

At block 204, the method 200 includes selecting the reward 306A based on whether the difference 308A between the output 302A and the output 302B is less than the threshold 310A. The output 302B is generated by the computational model 115B in response to receiving the input 304A. Functionality related to block 204 is described above with reference to FIG. 2.

At block 206, the method 200 includes updating the computational model 115A using the reward 306A. Functionality related to block 206 is described above with reference to FIG. 2.

At block 208, the method 215 includes using the computational model 115A to generate the output 302C in response to receiving the input 304A. Functionality related to block 208 is described above with reference to FIG. 2.

At block 210, the method 225 includes using the computational model 115A to generate the output 302E in response to receiving the input 304B. Functionality related to block 210 is described above with reference to FIG. 3.

At block 212, the method 225 includes selecting the reward 306B in the form of a negative reinforcement reward based on the difference 308C between the output 302E and the output 302F being greater than the threshold 310C. The output 302F is generated by the computational model 115B in response to receiving the input 304B. The threshold 310C is greater than the threshold 310A and/or the threshold 310B and has similar units to the threshold 310A and/or the threshold 310B. In this example, the reward 306B has a greater (e.g., negative) magnitude than the negative magnitude of the reward 306A. Functionality related to block 212 is described above with reference to FIG. 3.

At block 214, the method 225 includes updating the computational model 115A using the reward 306B. Functionality related to block 214 is described above with reference to FIG. 3.

At block 216, the method 235 includes using the computational model 115A to generate additional outputs 302X in response to receiving additional inputs 304. Functionality related to block 216 is described above with reference to FIG. 4.

At block 218, the method 235 includes determining a proportion 309 of the differences 308D between the outputs 302X and the outputs 302Y that are less than the threshold 310Z. The outputs 302Y are generated by the computational model 115B in response to receiving the inputs 304. Functionality related to block 218 is described above with reference to FIG. 4.

The description of the different advantageous arrangements has been presented for purposes of illustration and description, and is not intended to be exhaustive or limited to the examples in the form disclosed. Many modifications and variations will be apparent to those of ordinary skill in the art. Further, different advantageous examples may describe different advantages as compared to other advantageous examples. The example or examples selected are chosen and described in order to explain the principles of the examples, the practical application, and to enable others of ordinary skill in the art to understand the disclosure for various examples with various modifications as are suited to the particular use contemplated.

What is claimed is:

1. A method of training a first computational model to emulate a second computational model, the method comprising:
(a) using the first computational model to generate a first output in response to receiving an input;
(b) selecting a reward based on whether a difference between the first output and a second output is less than a threshold, wherein the second output is generated by the second computational model in response to receiving the input; and
(c) updating the first computational model using the reward.

2. The method of claim 1, wherein the first computational model is a machine learning model.

3. The method of claim 1, wherein the second computational model is a theoretical model, a simulated model, or a mathematical model.

4. The method of claim 1, wherein the input includes a first altitude or a first velocity of a first aircraft.

5. The method of claim 4, wherein the input further includes a second altitude or a second velocity of a second aircraft.

6. The method of claim 5, wherein the input further includes an aspect angle between the second velocity and a first orientation of the first aircraft.

7. The method of claim 5, wherein the input further includes a lead angle between the first velocity and a second orientation of the second aircraft.

8. The method of claim 5, wherein the input further includes a maximum acceleration capability of the second aircraft.

9. The method of claim 4, wherein the input further includes a type of a missile carried by the first aircraft or a range of the missile.

10. The method of claim 1, wherein the first output includes a distance over which a missile deployed by a first aircraft travels to reach a second aircraft.

11. The method of claim 1, wherein the first output includes a time of flight for a missile deployed by a first aircraft to reach a second aircraft.

12. The method of claim 1, wherein the difference is a first difference and the threshold is a first threshold, the method further comprising:
using the first computational model to generate a third output in response to receiving the input,
wherein selecting the reward comprises selecting the reward additionally based on whether a second difference between the third output and a fourth output is less than a second threshold, wherein the fourth output is generated by the second computational model in response to receiving the input.

13. The method of claim 12, wherein selecting the reward comprises selecting a positive reinforcement reward based on (a) the first difference being less than the first threshold and (b) the second difference being less than the second threshold.

14. The method of claim 12, wherein selecting the reward comprises selecting a negative reinforcement reward based on (a) the first difference being greater than the first threshold or (b) the second difference being greater than the second threshold.

15. The method of claim 14, wherein the negative reinforcement reward is a first negative reinforcement reward, the method further comprising:
using the first computational model to generate a fifth output in response to receiving a second input;
selecting a second negative reinforcement reward based on a third difference between the fifth output and a sixth output being greater than a third threshold, wherein the sixth output is generated by the second computational model in response to receiving the second input, wherein the third threshold is greater than the first threshold, and wherein the second negative reinforcement reward has greater magnitude than the first negative reinforcement reward; and
updating the first computational model using the second negative reinforcement reward.

16. The method of claim 1, further comprising repeating steps (a)-(c) multiple times.

17. The method of claim 1, further comprising:
using the first computational model to generate a third outputs in response to receiving second inputs; and
determining a proportion of differences between the third outputs and fourth outputs that are less than the threshold, wherein the fourth outputs are generated by the second computational model in response to receiving the second inputs.

18. A non-transitory computer readable medium storing instructions that, when executed by one or more processors of a computing device, cause the computing device to perform functions for training a first computational model to emulate a second computational model, the functions comprising:
(a) using the first computational model to generate a first output in response to receiving an input;
(b) selecting a reward based on whether a difference between the first output and a second output is less than a threshold, wherein the second output is generated by the second computational model in response to receiving the input; and
(c) updating the first computational model using the reward.

19. A computing device comprising:
one or more processors; and
a computer readable medium storing instructions that, when executed by the one or more processors, cause the computing device to perform functions for training a first computational model to emulate a second computational model, the functions comprising:
(a) using the first computational model to generate a first output in response to receiving an input;
(b) selecting a reward based on whether a difference between the first output and a second output is less than a threshold, wherein the second output is generated by the second computational model in response to receiving the input; and
(c) updating the first computational model using the reward.

20. The computing device of claim 19, wherein the first computational model is a machine learning model and the second computational model is a theoretical model, a simulated model, or a mathematical model.
